(19) United States
(12) Patent Application Publication
(10) Pub. No.: US 2026/0090420 A1
(43) Pub. Date: Mar. 26, 2026

(54) PACKAGE STRUCTURE AND FORMING METHOD THEREOF

(71) Applicant: JCET Management Co., Ltd., SHANGHAI CITY (CN)

(72) Inventor: Cheng Yang, Shanghai (CN)

(73) Assignee: JCET Management Co., Ltd., SHANGHAI CITY (CN)

(21) Appl. No.: 19/298,099

(22) Filed: Aug. 12, 2025

(30) Foreign Application Priority Data
Sep. 26, 2024 (CN) 202411351843.6

(51) Int. Cl. H01L 23/538; H01L 23/00; H01L 25/18; H10B 80/00; H10D 80/30

(52) U.S. Cl. CPC H10W 70/65; H10B 80/00; H10D 80/30; H10W 70/611; H10W 90/00; H10W 90/28; H10W 90/297; H10W 90/722; H10W 90/724

(57) ABSTRACT

A package structure and a forming method thereof are disclosed. In the package structure, two adjacent first chips arranged in a row direction are interconnected through a first wiring, two adjacent first chips arranged in a column direction are interconnected through a second wiring, and lengths of the first wiring and the second wiring are the same, so that two adjacent first chips can be interconnected in both the row direction and the column direction, thereby increasing connection channels and enhancing the bandwidth. In addition, since the lengths of the first wiring and the second wiring are the same, rates for various same or different communications or data transmissions between the two adjacent first chips arranged in rows and columns can remain consistent or vary slightly in the row direction and the column direction, thereby improving performance of the package structure.

### CROSS-REFERENCE TO RELATED APPLICATION

This application claims the priority benefit of China application serial no. 202411351843.6, filed on Sep. 26, 2024. The entirety of the above-mentioned patent application is hereby incorporated by reference herein and made a part of this specification.

### TECHNICAL FIELD

The present disclosure relates to the field of semiconductor packaging, and in particular, to a package structure and a forming method thereof.

### BACKGROUND

System-in-package (SiP) is a system that integrates chips with different functions such as optoelectronics, digital/logic, radio frequency, and storage in a single package in the form of chip stacking or package stacking, so that the system can achieve multiple functions.

Today, the demands of emerging fields (such as servers, mobile devices, artificial intelligence, automotive electronics, and data storage) for the amount of data computation increase exponentially. To meet the requirements of high-performance computing such as high density, high rate, high heat dissipation, low power consumption, and low latency, the existing system-in-package is expanding towards wafer scale, that is, a plurality of chip modules (die modules) with same or different functions are integrated on a silicon wafer to form a wafer-scale system-in-package structure.

Each existing chip module includes a logic chip (logic die) mounted on an interposer and a plurality of memory chips (memory dies) located on the interposers on both sides of the logic chip. As the logic chips of adjacent chip modules need to communicate or transfer data with each other, wiring is required in the interposer between the chip modules to achieve interconnection between the logic chips of adjacent chip modules.

Currently, the interconnection between the logic chips of the adjacent chip modules can only be connected through wiring in the Y direction, while in the X direction, memory chips are mounted between adjacent logic chips, and if wiring is performed in the X direction, a length of the wiring would increase compared with a length of wiring in the Y direction. In this case, a communication rate in the X direction between the adjacent logic chips is less than that in the Y direction, which affects performance of the package structure, and also increases the difficulty of wiring in the X direction.

### SUMMARY

The present disclosure provides a package structure and a forming method thereof, to ensure that communication rates of the chips in the package structure remains consistent or varies slightly in different directions, and to increase bandwidth, so as to improve performance of the package structure.

To resolve the foregoing problem, an aspect of the present disclosure provides a package structure, including:
a substrate, where the substrate has a plurality of discrete first wirings for interconnection in a row direction and a plurality of discrete second wirings for interconnection in a column direction, and a length of the second wiring is equal to a length of the first wiring;
a plurality of first chips, where the plurality of first chips are arranged in rows and columns on an upper surface of the substrate, two adjacent first chips arranged in the row direction are interconnected through the first wiring, and two adjacent first chips arranged in the column direction are interconnected through the second wiring; and
a second chip mounted on a back surface of the first chip, where the second chip is electrically connected to the first chip.

In an optional embodiment, the substrate includes an upper surface and a lower surface that are opposite to each other, the upper surface of the substrate has a plurality of discrete first pads and a plurality of discrete second pads, two ends of each first wiring are electrically connected to two corresponding first pads, and two ends of each second wiring is electrically connected to other two corresponding second pads.

In an optional embodiment, the first chip includes a back surface and an active surface that are opposite to each other, the back surface of the first chip has a plurality of discrete first connection terminals, and the active surface of the first chip has a plurality of discrete first solder bumps, where the first connection terminals are electrically connected to the corresponding first solder bumps, and some first solder bumps are soldered to the corresponding first pads and are then electrically connected to the corresponding first wirings, while other first solder bumps are soldered to the corresponding second pads and are then electrically connected to the corresponding second wirings.

In an optional embodiment, the second chip includes a back surface and an active surface that are opposite to each other, and the active surface of the second chip has a plurality of discrete second solder bumps; and that the second chip is electrically connected to the first chip includes the second solder bumps are soldered to the first connection terminals.

In an optional embodiment, the first chip is a logic chip, the second chip is a memory chip, and the third chip is a processing chip.

In an optional embodiment, two adjacent first chips arranged in the row direction are interconnected through the first wiring, and two adjacent first chips arranged in the column direction are interconnected through the second wiring, including two adjacent first chips arranged in the row direction are interconnected through some first solder bumps and the first wiring and perform communication or data transmission; and two adjacent first chips arranged in the column direction are interconnected through some first solder bumps and the second wiring and perform communication or data transmission.

In an optional embodiment, there are one or more second chips.

In an optional embodiment, when there is more than one second chip, the second chips are mounted respectively on the back surfaces of the first chips in a horizontal direction, or the second chips are sequentially stacked and mounted on the back surfaces of the first chips in a vertical direction.

In an optional embodiment, the first chip is a memory chip, and the second chip is a logic chip.

In an optional embodiment, when the two adjacent first chips arranged in the row direction are interconnected through the first wiring, and the two adjacent first chips arranged in the column direction are interconnected through the second wiring, there is no communication or data transmission between the two adjacent first chips.

In an optional embodiment, the two adjacent second chips arranged in the row direction are interconnected and communicate or transmit data through some second solder bumps on the second chip, some corresponding first connection terminals and first solder bumps on the first chip, and some corresponding first pads and first wirings in the substrate; and the two adjacent second chips arranged in the column direction are interconnected and communicate or transmit data through some other second solder bumps on the second chip, some other corresponding first connection terminals and first solder bumps on the first chip, and corresponding second pads and second wirings in the substrate.

In an optional embodiment, the upper surface of the substrate has a plurality of discrete third pads; the substrate also has a plurality of discrete third wirings, where the third wirings are electrically connected to the third pads; and some other first solder bumps on the first chip are soldered to the third pads.

In an optional embodiment, the package structure further includes a heat dissipation device mounted on the back surface of the second chip.

Another embodiment of the present disclosure further provides a forming method for a package structure, including:
providing a substrate, where the substrate has a plurality of discrete first wirings for interconnection in a row direction and a plurality of discrete second wirings for interconnection in a column direction, and a length of the second wiring is equal to a length of the first wiring;
providing a plurality of first chips, where the plurality of first chips are arranged in rows and columns on an upper surface of the substrate, two adjacent first chips arranged in the row direction are interconnected through the first wiring, and two adjacent first chips arranged in the column direction are interconnected through the second wiring; and
mounting a second chip on a back surface of the first chip, where the second chip is electrically connected to the first chip.

In an optional embodiment, the substrate includes an upper surface and a lower surface that are opposite to each other, the upper surface of the substrate has a plurality of discrete first pads and a plurality of discrete second pads, two ends of each first wiring are electrically connected to two corresponding first pads, and two ends of each second wiring is electrically connected to other two corresponding second pads.

In an optional embodiment, the first chip includes a back surface and an active surface that are opposite to each other, the back surface of the first chip has a plurality of discrete first connection terminals, and the active surface of the first chip has a plurality of discrete first solder bumps, where the first connection terminals are electrically connected to the corresponding first solder bumps; and when the plurality of first chips are arranged in rows and columns on an upper surface of the substrate, some first solder bumps are soldered to the corresponding first pads and are then electrically connected to the corresponding first wirings, while other first solder bumps are soldered to the corresponding second pads and are then electrically connected to the corresponding second wirings.

In an optional embodiment, the second chip includes a back surface and an active surface that are opposite to each other, and the active surface of the second chip has a plurality of discrete second solder bumps; and when the second chip is mounted on the back surface of the first chip, the second solder bumps are soldered to the first connection terminals.

In an optional embodiment, the first chip is a logic chip, and the second chip is a memory chip; or the first chip is a memory chip, and the second chip is a logic chip.

In an optional embodiment, there are one or more second chips; and when there is more than one second chip, the second chips are mounted respectively on the back surfaces of the first chips in a horizontal direction, or the second chips are sequentially stacked and mounted on the back surfaces of the first chips in a vertical direction.

In an optional embodiment, the forming method for a package structure further includes mounting a heat dissipation device on the back surface of the second chip.

The technical solutions of the present disclosure have the following advantages:

The present disclosure provides a package structure and a forming method thereof. The package structure includes: a substrate, where the substrate has a plurality of discrete first wirings for interconnection in a row direction and a plurality of discrete second wirings for interconnection in a column direction, and a length of the second wiring is equal to a length of the first wiring; a plurality of first chips, where the plurality of first chips are arranged in rows and columns on an upper surface of the substrate, two adjacent first chips arranged in the row direction are interconnected through the first wiring, and two adjacent first chips arranged in the column direction are interconnected through the second wiring; and a second chip mounted on a back surface of the first chip, where the second chip is electrically connected to the first chip. That is, in the package structure according to the present disclosure, the two adjacent first chips arranged in the row direction are interconnected through the first wiring, the two adjacent first chips arranged in the column direction are interconnected through the second wiring, and the lengths of the first wiring and the second wiring are the same, so that two adjacent first chips in the plurality of first chips arranged in rows and columns can be interconnected in both the row direction and the column direction, thereby increasing channels of connection and enhancing the bandwidth. In addition, since the lengths of the first wiring used for interconnection in the row direction and the second wiring used for interconnection in the column direction are the same, rates for various same or different communications or data transmissions between the two adjacent first chips arranged in rows and columns can remain consistent or vary slightly in the row direction and the column direction, thereby improving performance of the package structure. In addition, since the second chip is mounted on the back surface of the first chip. This shortens the connection distance between the second chip and the first chip, thereby increasing the communication rate between them; and this does not occupy the mounting space on the surface of the substrate between adjacent first chips or the wiring space in the substrate, thereby simplifying wiring of the first and second wirings in the substrate and making it easier for the length of the first wiring to be equal to the length of the second wiring.

### BRIEF DESCRIPTION OF DRAWINGS

FIG. 1 to FIG. 3 are schematic diagrams of a package structure according to an embodiment of the present disclosure, where FIG. 2 is a cross-sectional view of FIG. 1 along a cutting line AA1, and FIG. 3 is a cross-sectional view of FIG. 1 along a cutting line BB1;

FIG. 4 to FIG. 6 are schematic diagrams of a package structure according to another embodiment of the present disclosure, where FIG. 5 is a cross-sectional view of FIG. 4 along a cutting line AA1, and FIG. 6 is a cross-sectional view of FIG. 4 along a cutting line BB1; and

FIG. 4, FIG. 7, and FIG. 8 are schematic diagrams of a package structure according to yet another embodiment of the present disclosure, where FIG. 7 is a cross-sectional view of FIG. 4 along a cutting line AA1, and FIG. 8 is a cross-sectional view of FIG. 4 along a cutting line BB1.

### DETAILED DESCRIPTION OF EMBODIMENTS

The following describes specific implementations of the present disclosure in detail with reference to the accompanying drawings. When embodiments of the present disclosure are described in detail, for ease of description, schematic diagrams are not partially enlarged according to a general proportion. In addition, the schematic diagrams are merely examples and should not limit the protection scope of the present disclosure. In addition, the length, width, and depth of a three-dimensional space should be included in actual manufacture.

An embodiment of the present disclosure first provides a package structure. The package structure according to the present disclosure is described in detail below with reference to the accompanying drawings.

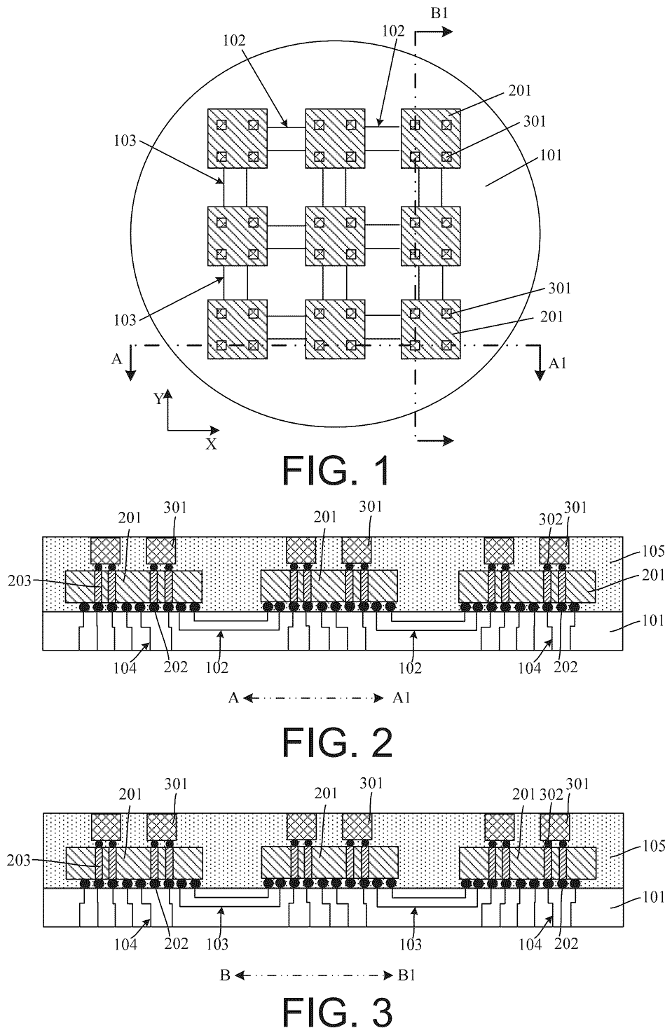

An embodiment of the present disclosure provides a package structure. Referring to FIG. 1 to FIG. 3, FIG. 2 is a cross-sectional view of FIG. 1 along a cutting line AA1, and FIG. 3 is a cross-sectional view of FIG. 1 along a cutting line BB1. The package structure includes:
a substrate 101, where the substrate 101 as a plurality of discrete first wirings 102 for interconnection in a row direction and a plurality of discrete second wirings 103 for interconnection in a column direction, and a length of the second wiring 103 is equal to a length of the first wiring 102;
a plurality of first chips 201, where the plurality of first chips 201 are arranged in rows and columns on an upper surface of the substrate 101, two adjacent first chips 201 arranged in the row direction are interconnected through the first wiring 102, and two adjacent first chips 201 arranged in the column direction are interconnected through the second wiring 103; and
a second chip 301 mounted on a back surface of the first chip 201, where the second chip 301 is electrically connected to the first chip 201.

The substrate 101 serves as a support carrier and a connecting carrier of the package structure. In an embodiment, the upper surface of the substrate 101 has a plurality of discrete first pads (not shown in the figure) and a plurality of discrete second pads (not shown in the figure). The substrate 101 includes a plurality of discrete first wirings 102 for interconnection in the row direction and a plurality of discrete second wirings 103 for interconnection in the column direction, where two ends of each first wiring 102 are electrically connected to two corresponding first pads, and two ends of each second wiring 103 are electrically connected to other two corresponding second pads. When the plurality of first chips 201 are arranged in rows and columns and mounted on the upper surface of the substrate 101, the two adjacent first chips 201 arranged in the row direction are electrically connected to corresponding first pads for interconnection through the first wiring 102, and the two adjacent first chips 201 arranged in the column direction are electrically connected to corresponding second pads for interconnection through the second wiring 103. It should be noted that in an embodiment, the row direction is the X-axis direction, and the column direction is the Y-axis direction.

In an embodiment, the plurality of discrete first wirings 102 are divided into a plurality of groups, each group of the first wirings includes a plurality of discrete first wiring 102, and each group of the first wirings is used to connect two adjacent first chips 201 in a plurality of first chips 201 arranged in the row direction; and the plurality of groups of the first wirings are arranged in rows and columns on the substrate 101, and each group of the first wirings is located in the substrate 101 between two adjacent first chips 201 arranged in the row direction. In an embodiment, a plurality of first wirings 102 in the first wirings of different groups are arranged in the same way. In an embodiment, lengths of a plurality of first wirings 102 in each group of the first wirings are the same. In another embodiment, lengths of some first wiring 102 in each group of the first wirings are the same, and lengths of some other first wirings 102 are different.

In an embodiment, the plurality of discrete second wirings 103 are divided into a plurality of groups, each group of the second wirings includes a plurality of discrete second wiring 103, and each group of the second wirings is used to connect two adjacent second chips 301 in a plurality of second chips 301 arranged in the column direction; and the plurality of groups of the second wirings are arranged in rows and columns on the substrate 101, and each group of the second wirings is located in the substrate 101 between two adjacent first chips 201 arranged in the column direction. In an embodiment, a plurality of second wirings 103 in the second wirings of different groups are arranged in the same way. In an embodiment, lengths of a plurality of second wirings 103 in each group of the second wirings are the same. In another embodiment, lengths of some second wiring 103 in each group of the second wirings are the same, and the lengths of some other second wirings 103 are different.

The length of the second wiring 103 is equal to the length of the first wiring 102, which includes two scenarios. In the first scenario, when the lengths of a plurality of first wirings 102 in each group of the first wirings are the same, and the lengths of a plurality of second wirings 103 in each group of the second wirings are the same, the lengths of a plurality of first wirings 102 in each group of the first wirings are the same as the lengths of a plurality of second wirings 103 in each group of the second wirings. In the second scenario, when the lengths of some first wiring 102 in each group of the first wirings are the same, while the lengths of some other first wirings 102 are different, and the lengths of some second wirings 103 in each group of the second wirings are the same, while the lengths of some other second wirings 103 are different, the lengths of the second wiring 103 and the first wiring 102 in each group that have same function are the same, or the lengths of the second wiring 103 and the first wiring 102 in each group that transmit the same signal are the same, or the lengths of the second wiring 103 and the first wiring 102 in each group that transmit the same data are the same. That is, in the present disclosure, the two adjacent first chips 201 arranged in the row direction are interconnected through the first wiring 102, the two adjacent first chips 201 arranged in the column direction are interconnected through the second wiring 103, and the lengths of the first wiring 102 and the second wiring 103 are the same, so that two adjacent first chips 201 in the plurality of first chips 201 arranged in rows and columns can be interconnected in both the row direction and the column direction, thereby increasing connection channels and enhancing the bandwidth. In addition, since the lengths of the first wiring 102 used for interconnection in the row direction and the second wiring 103 used for interconnection in the column direction are the same, rates for various same or different communications or data transmissions between the two adjacent first chips 201 arranged in rows and columns in the plurality of first chips can remain consistent or vary slightly in the row direction and the column direction, thereby improving performance of the package structure.

In an embodiment, the upper surface of the substrate 101 also has a plurality of discrete third pads (not shown in the figure), and the lower surface of the substrate 101 may also have a plurality of discrete fourth pads (not shown in the figure). An external protrusion may be formed on the lower surface of the second pad (not shown in the figure), and the external protrusion is used for electrical connection with other devices, substrates, or package structures. The substrate 101 also has a plurality of discrete third wirings 104, where one end of each third wiring 104 is electrically connected to the corresponding third pad. In a specific embodiment, the other end of the third wiring 104 can be electrically connected to the corresponding fourth pad on the lower surface of the substrate 101. In another specific embodiment, the other end of the third wiring 104 can be electrically connected to another third pad on the upper surface of the substrate 101. In yet another specific embodiment, the other end of the third wiring 104 can be electrically connected to the corresponding first pad or second pad on the upper surface of the substrate 101. In an embodiment, the first chip 201 is not only electrically connected to the first wiring 102 and the second wiring 103, but the first chip 201 can also be electrically connected to the third pad and the third wiring 104.

In an embodiment, the first wiring 102, second wiring 103, and third wiring 104 may include one or more of a metal layer, connecting plugs, through silicon via (TSV) connection structures, via connection structures, or metal conductive pillars. In an embodiment, the first pad, the second pad, the third pad, the fourth pad, the first wiring 102, the second wiring 103, and the third wiring 104 are made of a metal, where the metal may be specifically one or more of aluminum, copper, nickel, tin, titanium, tungsten, platinum, chromium, tantalum, gold, or silver. The external protrusion is made of tin or a tin alloy, where the tin alloy is one or more of tin-silver, tin-indium, tin-gold, tin-copper, tin-lead, tin-silver-copper, tin-silver-zinc, tin-zinc, tin-bismuth-indium, tin-zinc-indium, or tin-silver-antimony.

In an embodiment, the substrate 101 can be one of a silicon substrate, a redistribution layer (RDL) substrate, a resin substrate, a printed circuit board (PCB), a ceramic substrate, a glass substrate, or a flexible circuit board (FPC). In an embodiment, the substrate can be a single-layer board or a multi-layer board. In an embodiment, the substrate 101 may serve as an interposer. In an embodiment, the substrate 101 may be a silicon wafer.

In an embodiment, the substrate 101 may have a large size. When the substrate 101 is circular, a diameter of the substrate 101 can be 300 mm±10 mm or 450 mm±15 mm. When the substrate 101 is square, a diagonal dimension of the substrate 101 can be 300 mm±15 mm or 450 mm±20 mm.

The first chip 201 is mounted on the upper surface of the substrate 101 by using a flip-chip process. In an embodiment, the first chip 201 includes a back surface and an active surface that are opposite to each other, and the back surface of the first chip 201 has a plurality of discrete first connection terminals 203, where the first connection terminals 203 include through silicon via (TSV) interconnect structures, or TSV interconnect structures connected to the top of the pads; the active surface of the first chip 201 has a plurality of discrete first solder bumps 202, where the first connection terminals 203 are electrically connected to corresponding first solder bumps 202. The plurality of discrete first solder bumps 202 can be divided into multiple parts. Some first solder bumps 202 are soldered to the corresponding first pads and are then electrically connected to the first wiring 102, so that the two adjacent first chips 201 arranged in the row direction are interconnected through the first wiring 102 (refer to FIG. 1 and FIG. 2); and some other first solder bumps 202 are soldered to the corresponding second pads and are then electrically connected to the second wiring 103, so that the two adjacent first chips 201 arranged in the column direction are interconnected through the second wiring 103 (refer to FIG. 1 and FIG. 3). In an embodiment, some other first solder bumps 202 on the first chip 201 are soldered to the third pad and are then electrically connected to the third wiring 104.

In an embodiment, an integrated circuit (with specific functions) (such as a logic control circuit, not shown in the figure) is formed in the first chip 201, and the first solder bumps 202 and the first connection terminals 203 are electrically connected to the integrated circuit. In a specific embodiment, the first solder bump 202 can be a solder protrusion or can include a metal bump and a solder layer located on the top surface of the metal bump. In a specific embodiment, the first connection terminal 203 is made of one or more of aluminum, copper, titanium, nickel, tin, tungsten, platinum, chromium, tantalum, gold, or silver; the metal bump is made of one or more of aluminum, copper, titanium, nickel, tin, tungsten, platinum, chromium, tantalum, gold, or silver; and the solder bump or solder layer is made of tin or a tin alloy, where the tin alloy is one or more of tin-silver, tin-indium, tin-gold, tin-copper, tin-lead, tin-silver-copper, tin-silver-zinc, tin-zinc, tin-bismuth-indium, tin-zinc-indium, or tin-silver-antimony.

The second chip 301 is mounted on the back surface of the first chip 201 by using a flip-chip process. In an embodiment, the second chip 301 has a back surface and an active surface that are opposite to each other, and the active surface of the second chip 301 has a plurality of discrete second solder bumps 302; and that the second chip 301 is electrically connected to the first chip 201 includes: the second solder bumps 302 are soldered to the first connection terminal 203. In the present disclosure, when the second chip 301 is mounted on the back surface of the first chip 201, the connection distance between the second chip 301 and the first chip 201 is shortened, thereby increasing the communication rate between the second chip 301 and the first chip 201. In addition, the mounting space on the surface of the substrate 101 between the adjacent first chips 201 and the wiring space within the substrate 101 is not occupied, thereby simplifying the wiring of the first wiring 102 and the second wiring 103 in the substrate 101, and making it easier to ensure that the length of the first wiring 102 equals the length of the second wiring 103.

There are one or more second chips 301. In an embodiment, referring to FIG. 1 to FIG. 3, when there are a plurality of (which may be specifically 2, 3, 4, or more) second chips 301, the plurality of second chips 301 are mounted on the back surface of the first chip 201 in the horizontal direction (parallel to the upper surface of the substrate 101).

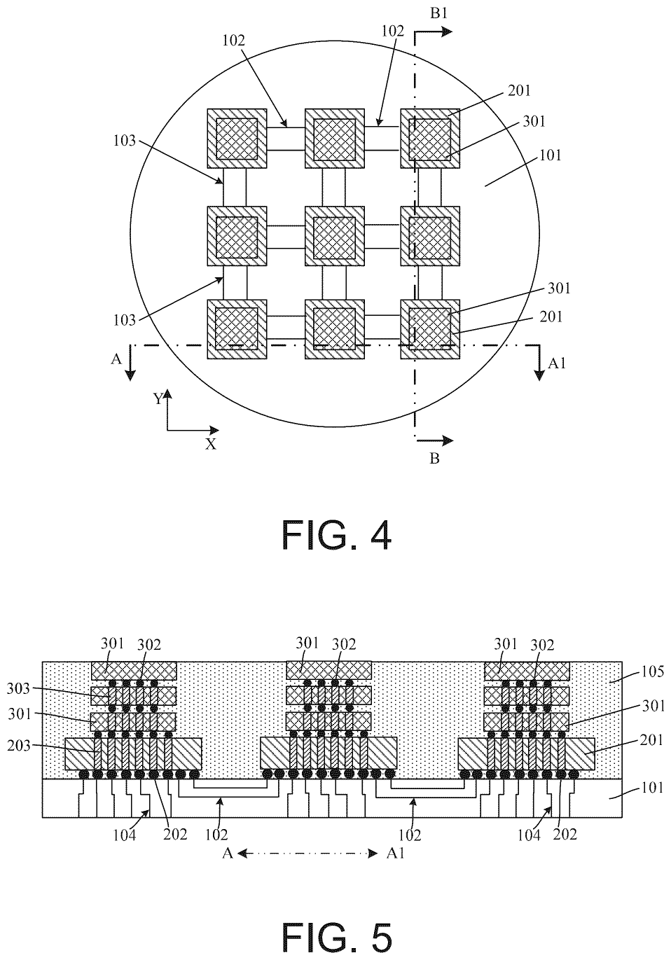

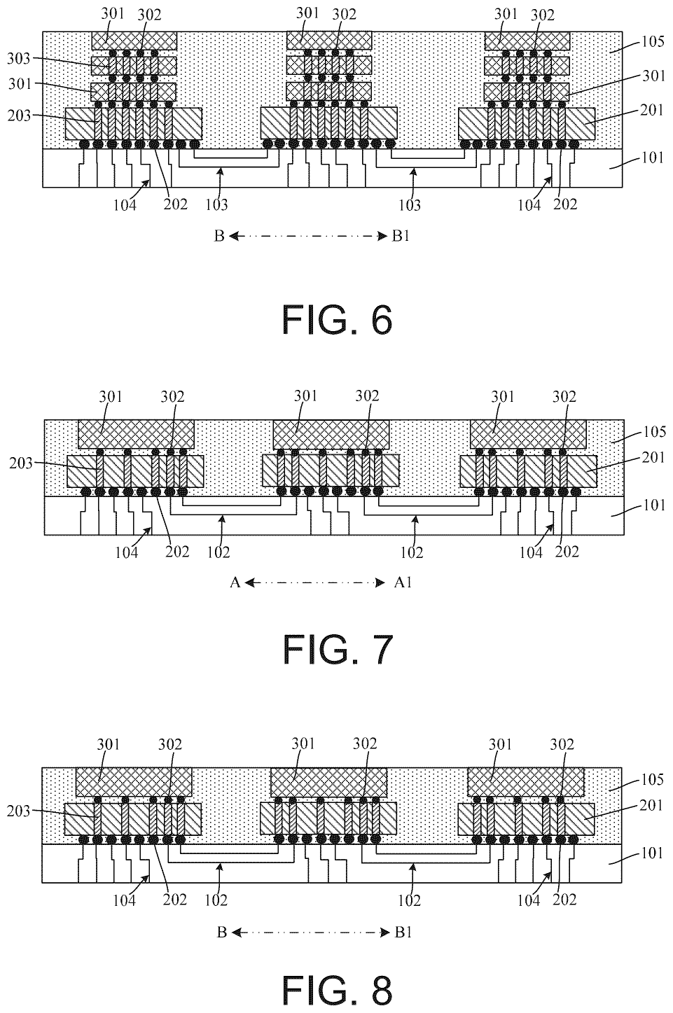

In another embodiment, referring to FIG. 4 to FIG. 6, FIG. 5 is a cross-sectional view of FIG. 4 along a cutting line AA1, and FIG. 6 is a cross-sectional view of FIG. 4 along a cutting line BB1. When there a plurality of (which may be specifically 2, 3, 4, or more) second chips 301, the plurality of second chips 301 are sequentially stacked and mounted on the back surface of the first chip 201 in the vertical direction. Specifically, the back surface of the second chip 301 includes second connection terminals 303, where the second connection terminal 303 includes a through silicon via (TSV) interconnect structure, or a TSV interconnect structure with a pad connected to the top of the TSV. When a plurality of second chips 301 are stacked in the vertical direction, the second solder bumps 302 on the active surface of the upper second chip 301 are soldered to the second connection terminals 303 on the back surface of the adjacent lower second chip 301, and the second solder bumps 302 on the active surface of the bottommost second chip 301 are soldered to the first connection terminals 203 on the back surface of the first chip 201. It should be noted that the back surface of the topmost second chip 301 may not have the second connection terminal 303.

In an embodiment, the second connection terminal 303 is made of one or more of aluminum, copper, titanium, nickel, tin, tungsten, platinum, chromium, tantalum, gold, or silver.

In an embodiment, an integrated circuit with specific functions is formed in the second chip 301, and the second connection terminals 303 and the second solder bumps 302 are electrically connected to the integrated circuit.

In an embodiment, the second solder bump 302 is a micro bump (μ bump). The micro bump 302 is made of tin or a tin alloy, and the tin alloy is one or more of tin-silver, tin-indium, tin-gold, tin-copper, tin-lead, tin-silver-copper, tin-silver-zinc, tin-zinc, tin-bismuth-indium, tin-zinc-indium, or tin-silver-antimony.

In other embodiments, the active surface of the second chip 301 may not have micro bumps, but instead has a plurality of discrete bonding metal layers. The plurality of second chips 301 are sequentially stacked and mounted on the back surface of the first chip 201 in the vertical direction, and the bonding connection between the upper and lower second chips 301 is not made through micro bumps, but rather by using a hybrid bonding method (including metal diffusion bonding and silicon-oxygen bonding).

In an embodiment, still referring to FIG. 1 to FIG. 3 or FIG. 4 to FIG. 6, the package structure further includes: a molding layer 105 that covers the second chip 301 and the first chip 201 and filled between the second chip 301 and the first chip 201 and between the first chip 201 and the upper surface of the substrate 101. The molding layer 105 may expose or not expose the back surface of the second chip 301.

In an embodiment, the molding layer 105 is made of liquid epoxy molding compound (LMC). In other embodiments, the molding layer 105 can also be made of other liquid resin molding compounds, such as liquid polyimide resin molding compound, liquid cyclopentene resin molding compound, or liquid polybenzimidazole resin molding compound. In other embodiments, the molding layer 105 may alternatively be made of other resin materials containing or not containing fillers.

The functions of the first chip 201 and the second chip 301 are different. In an embodiment, still referring to FIG. 1 to FIG. 3 or FIG. 4 to FIG. 6, the first chip 201 is a logic chip, and the second chip 301 is a memory chip, where the memory chip is used to store data, and the logic chip is used to control and manage the memory chip. The memory chips include, but are not limited to, dynamic random access memory (DRAM), static random-access memory (SRAM), magnetoresistive random access memory (MRAM), phase-change RAM (PRAM), and resistive random access memory (RRAM). The logic chips include, but are not limited to, graphics processing unit (GPU), field-programmable gate array (FPGA), application-specific integrated circuit (ASIC), central processing unit (CPU), microprocessing unit (MPU), microcontroller unit (MCU), logic integrated circuit (IC), application processor (AP), or other known electronic circuits used as processors.

In an embodiment, still referring to FIG. 1 to FIG. 3 or FIG. 4 to FIG. 6, when the first chip 201 is a logic chip and the second chip 301 is a memory chip, that the two adjacent first chips 201 arranged in the row direction are interconnected through the first wiring 102, and two adjacent first chips 201 arranged in the column direction are interconnected through the second wiring 103 includes: the two adjacent first chips 201 arranged in the row direction are interconnected through some first solder bumps 202 and the first wirings 102 and perform communication or data transmission, and the two adjacent first chips 201 arranged in the column direction are interconnected through some first solder bumps 202 and the second wirings 103 and perform communication or data transmission. However, there is no direct connection between the adjacent second chips 201 in the row direction or the column direction.

In another embodiment, referring to FIG. 4, FIG. 7, and FIG. 8, FIG. 7 is a cross-sectional view of FIG. 4 along a cutting line AA1, and FIG. 8 is a cross-sectional view of FIG. 4 along a cutting line BB1. The first chip 201 is a memory chip, and the second chip 301 is a logic chip. The two adjacent first chips 201 arranged in the row direction are interconnected through the first wiring 102. When the two adjacent first chips 201 arranged in the column direction are interconnected through the second wiring 103, there is no communication or data transmission between the two adjacent first chips 201. Specifically, the two adjacent second chips 301 arranged in the row direction are interconnected through some second solder bumps 302 on the second chip 301, some corresponding first connection terminals 203 and first solder bumps 202 on the first chip 201, and corresponding first pads and first wirings 102 in the substrate 101 and perform communication or data transmission (refer to FIG. 4 and FIG. 7); and the two adjacent second chips 301 arranged in the column direction are interconnected through some other second solder bumps 302 on the second chip 301, some other corresponding first connection terminals 203 and first solder bumps 202 on the first chip 201, and corresponding second pads and second wirings 103 in the substrate 101 and perform communication or data transmission (refer to FIG. 4 and FIG. 8). When the logic chip (the second chip 301) is mounted above the memory chip (the first chip 201), the memory chip is used to store data, and the logic chip is used to control and manage the memory chip. Communication or data transmission can be performed between adjacent logic chips (the second chips 301) in the row or column direction, while there is no communication or data transmission between adjacent memory chips (the first chips 201) in the row or column direction. Since the lengths of the first connection terminals 203 are the same, and the lengths of the second wiring 103 and the first wiring 102 are also the same, during various same or different communications or data transmissions between adjacent first chips 201 arranged in rows and columns in the plurality of first chips 201, rates in the row direction and the column direction can be the same or slightly different. This enhances the performance of the package structure and increases connection channels, thereby improving bandwidth. In addition, since the logic chip generates a significant amount of heat during operation, in the package structure according to this embodiment, when the logic chip (the second chip 301) is mounted on the back surface of the memory chip (the first chip 201), a heat dissipation device can be easily mounted on the back surface of the logic chip (the second chip 301). This heat dissipation device releases or dissipates the heat from the logic chip (the second chip 301), thereby facilitating heat dissipation of the package structure and further improving the performance of the package structure.

In an embodiment, the logical chip and the memory chip are implemented in a three-dimensional stacking manner through wafer to wafer (w2w) hybrid bonding, thereby achieving a higher wafer alignment accuracy and a higher efficiency.

In an embodiment, that the molding layer 105 exposes or does not expose the back surface of the second chip 301 further includes: a heat dissipation device is mounted on the back surface of the second chip 301, where the heat dissipation device is a heat sink or a radiator, and the radiator includes an air cooling radiator or a liquid cooling radiator.

Another aspect of the present disclosure further provides a forming method for a package structure. In an embodiment, referring to FIG. 1 to FIG. 3, the forming method for package structure includes:

providing a substrate 101, where the substrate 101 includes a plurality of discrete first wirings 102 for interconnection in a row direction and a plurality of discrete second wirings 103 for interconnection in a column direction, and a length of the second wiring 103 is equal to a length of the first wiring 102;
providing a plurality of first chips 201, where the plurality of first chips 201 are arranged in rows and columns on an upper surface of the substrate 101, two adjacent first chips 201 arranged in the row direction are interconnected through the first wiring 102, and two adjacent first chips 201 arranged in the column direction are interconnected through the second wiring 103; and
mounting a second chip 301 on a back surface of the first chip 201, where the second chip 301 is electrically connected to the first chip 201.

In an embodiment, the substrate 101 includes an upper surface and a lower surface that are opposite to each other, the upper surface of the substrate 101 has a plurality of discrete first pads (not shown in the figure) and a plurality of discrete second pads (not shown in the figure), two ends of each first wiring 102 are electrically connected to two corresponding first pads, and two ends of each second wiring 103 is electrically connected to other two corresponding second pads.

In an embodiment, the first chip 201 includes a back surface and an active surface that are opposite to each other, the back surface of the first chip 201 has a plurality of discrete first connection terminals 203, and the active surface of the first chip 201 has a plurality of discrete first solder bumps 202, where the first connection terminals 203 are electrically connected to the corresponding first solder bumps 202; and when the plurality of first chips 201 are arranged in rows and columns on an upper surface of the substrate 101, some first solder bumps 202 are soldered to the corresponding first pads and are then electrically connected to the corresponding first wirings 102, while other first solder bumps 202 are soldered to the corresponding second pads and are then electrically connected to the corresponding second wirings 103.

In an embodiment, the second chip 301 includes a back surface and an active surface that are opposite to each other, and the active surface of the second chip 301 has a plurality of discrete second solder bumps; and when the second chip is mounted on the back surface of the first chip, the second solder bumps are soldered to the first connection terminals.

In an embodiment, referring to FIG. 1 to FIG. 3 or referring to FIG. 4 to FIG. 6, the first chip 201 is a logic chip, and the second chip 301 is a memory chip; or referring to FIG. 4, FIG. 7, and FIG. 8, the first chip 201 is a memory chip, and the second chip 301 is a logic chip.

In an embodiment, there are one or more second chips 301; and when there is more than one second chip 301, the second chips 301 are mounted on the back surface of the first chip in a horizontal direction (refer to FIG. 1 to FIG. 3), or the second chips 301 are sequentially stacked and mounted on the back surface of the first chip 201 in a vertical direction (refer to FIG. 4 to FIG. 6).

In an embodiment, the forming method for a package structure further includes mounting a heat dissipation device (not shown in the figure) on the back surface of the second chip 301.

It should be noted that the parts of this embodiment (the forming method for a package structure) that are the same or similar to those in the foregoing embodiment (the package structure) will not be repeated here; and for details, reference may be made to the limitations or descriptions in the corresponding parts in the foregoing embodiment.

The present disclosure has been described with reference to the preferred embodiments, which are not used to limit the present disclosure. Those skilled in the art can make possible variations and modifications to the present disclosure using the disclosed methods and technical contents without departing from the spirit and scope of the present disclosure; and therefore, any simple modifications, equivalent changes and modifications made to the foregoing embodiments according to the technical spirit of the present disclosure without departing from the content of the technical solutions of the present disclosure shall fall within the protection scope of the technical solutions of the present disclosure.

What is claimed is:

1. A package structure, comprising:
a substrate, wherein the substrate has a plurality of discrete first wirings for interconnection in a row direction and a plurality of discrete second wirings for interconnection in a column direction, and a length of the second wiring is equal to a length of the first wiring;
a plurality of first chips, wherein the plurality of first chips are arranged in rows and columns on an upper surface of the substrate, two adjacent first chips arranged in the row direction are interconnected through the first wiring, and two adjacent first chips arranged in the column direction are interconnected through the second wiring; and
a second chip mounted on a back surface of the first chip, wherein the second chip is electrically connected to the first chip.

2. The package structure according to claim 1, wherein the substrate comprises an upper surface and a lower surface that are opposite to each other, the upper surface of the substrate has a plurality of discrete first pads and a plurality of discrete second pads, two ends of each first wiring are electrically connected to two corresponding first pads, and two ends of each second wiring is electrically connected to other two corresponding second pads.

3. The package structure according to claim 2, wherein the first chip comprises a back surface and an active surface that are opposite to each other, the back surface of the first chip has a plurality of discrete first connection terminals, and the active surface of the first chip has a plurality of discrete first solder bumps, wherein the first connection terminals are electrically connected to the corresponding first solder bumps, and some first solder bumps are soldered to the corresponding first pads and are then electrically connected to the corresponding first wirings, while other first solder bumps are soldered to the corresponding second pads and are then electrically connected to the corresponding second wirings.

4. The package structure according to claim 3, wherein the second chip comprises a back surface and an active surface that are opposite to each other, and the active surface of the second chip has a plurality of discrete second solder bumps; and that the second chip is electrically connected to the first chip comprises: the second solder bumps are soldered to the first connection terminals.

5. The package structure according to claim 4, wherein the first chip is a logic chip, and the second chip is a memory chip.

6. The package structure according to claim 5, wherein that the two adjacent first chips arranged in the row direction are interconnected through the first wiring, and the two adjacent first chips arranged in the column direction are interconnected through the second wiring comprises the two adjacent first chips arranged in the row direction are interconnected through some first solder bumps and the first wirings and perform communication or data transmission; and the two adjacent first chips arranged in the column direction are interconnected through some first solder bumps and the second wirings and perform communication or data transmission.

7. The package structure according to claim 5, wherein there are one or more second chips.

8. The package structure according to claim 7, wherein when there is more than one second chip, the second chips are mounted respectively on the back surfaces of the first chips in a horizontal direction, or the second chips are sequentially stacked and mounted on the back surfaces of the first chips in a vertical direction.

9. The package structure according to claim 4, wherein the first chip is a memory chip, and the second chip is a logic chip.

10. The package structure according to claim 9, wherein the two adjacent first chips arranged in the row direction are interconnected through the first wiring, and the two adjacent first chips arranged in the column direction are interconnected through the second wiring, there is no communication or data transmission between the two adjacent first chips.

11. The package structure according to claim 10, wherein the two adjacent second chips arranged in the row direction are interconnected and communicate or transmit data through some second solder bumps on the second chip, some corresponding first connection terminals and first solder bumps on the first chip, and some corresponding first pads and first wirings in the substrate; and the two adjacent second chips arranged in the column direction are interconnected and communicate or transmit data through some other second solder bumps on the second chip, some other corresponding first connection terminals and first solder bumps on the first chip, and corresponding second pads and second wirings in the substrate.

12. The package structure according to claim 3, wherein the upper surface of the substrate has a plurality of discrete third pads; the substrate also has a plurality of discrete third wirings, wherein the third wirings are electrically connected to the third pads; and some other first solder bumps on the first chip are soldered to the third pads.

13. The package structure according to claim 1, further comprising a heat dissipation device mounted on the back surface of the second chip.

14. A forming method for a package structure, comprising:
providing a substrate, wherein the substrate has a plurality of discrete first wirings for interconnection in a row direction and a plurality of discrete second wirings for interconnection in a column direction, and a length of the second wiring is equal to a length of the first wiring;
providing a plurality of first chips, wherein the plurality of first chips are arranged in rows and columns on an upper surface of the substrate, two adjacent first chips arranged in the row direction are interconnected through the first wiring, and two adjacent first chips arranged in the column direction are interconnected through the second wiring; and
mounting a second chip on a back surface of the first chip, wherein the second chip is electrically connected to the first chip.

15. The forming method for the package structure according to claim 14, wherein the substrate comprises an upper surface and a lower surface that are opposite to each Method other, the upper surface of the substrate has a plurality of discrete first pads and a plurality of discrete second pads, two ends of each first wiring are electrically connected to two corresponding first pads, and two ends of each second wiring is electrically connected to other two corresponding second pads.

16. The forming method for the package structure according to claim 15, wherein the first chip comprises a back surface and an active surface that are opposite to each other, the back surface of the first chip has a plurality of discrete first connection terminals, and the active surface of the first chip has a plurality of discrete first solder bumps, wherein the first connection terminals are electrically connected to the corresponding first solder bumps, and when the plurality of first chips are arranged in rows and columns on a top surface of the substrate, some first solder bumps are soldered to the corresponding first pads and are then electrically connected to the corresponding first wirings, while other first solder bumps are soldered to the corresponding second pads and are then electrically connected to the corresponding second wirings.

17. The forming method for the package structure according to claim 16, wherein the second chip comprises a back surface and an active surface that are opposite to each other, and the active surface of the second chip has a plurality of discrete second solder bumps; and when the second chip is mounted on the back surface of the first chip, the second solder bumps are soldered to the first connection terminals.

18. The forming method for the package structure according to claim 17, wherein the first chip is a logic chip, and the second chip is a memory chip; or the first chip is a logic chip, and the second chip is a memory chip.

19. The forming method for the package structure according to claim 18, wherein there are one or more second chips; and when there is more than one second chip, the second chips are mounted respectively on the back surfaces of the first chips in a horizontal direction, or the second chips are sequentially stacked and mounted on the back surfaces of the first chips in a vertical direction.

20. The forming method for the package structure according to claim 14, further comprising mounting a heat dissipation device on the back surface of the second chip.
